(19) United States
(12) Patent Application Publication
(10) Pub. No.: US 2011/0155228 A1
(43) Pub. Date: Jun. 30, 2011

(54) DYE-SENSITIZED SOLAR CELL AND METHOD for FORMING THE SAME

(75) Inventors: Yung-Liang Tung, Hualien County (TW); Yao-Shan Wu, Kaohsiung City (TW); Ming-De Lu, Miaoli County (TW)

(73) Assignee: INDUSTRIAL TECHNOLOGY RESEARCH INSTITUTE, Hsinchu County (TW)

(21) Appl. No.: 12/878,240

(22) Filed: Sep. 9, 2010

(30) Foreign Application Priority Data
Dec. 30, 2009 (TW) 098145763

(51) Int. Cl. H01L 31/04; H01L 31/18; H01L 51/48

(52) U.S. Cl. 136/255; 136/252; 427/74; 205/183; 204/192.1; 438/82; 977/774; 257/E51.027

(57) ABSTRACT

The present invention provides a dye-sensitized solar cell (DSSC), comprising: a substrate having a first electrode formed thereon; a plurality of nanoparticles adsorbed with dye, overlying the first electrode; a solid electrolyte containing metal quantum dots completely covering the nanoparticles and fully filling the space between the nanoparticles; and a second electrode overlying the solid electrolyte. The present invention further provides a method for forming the dye-sensitized solar cell.

### CROSS REFERENCE TO RELATED APPLICATIONS

This application claims priority of Taiwan Patent Application No. 098145763, filed on Dec. 30, 2009, the entirety of which is incorporated by reference herein.

### BACKGROUND OF THE INVENTION

1. Field of the Invention

The present invention relates to a dye-sensitized solar cell, and in particular relates to a solid-state dye-sensitized solar cell having metal quantum dots.

2. Description of the Related Art

Solar energy is one of a number of alternative energy sources that is gaining worldwide attention due to its renewable properties, abundance, availability and environmentally friendliness. At present, solar energy is being used in replace of existing non-renewable energy sources.

When a photo sensitive substance of a solar cell is illuminated by light, electron-hole pairs (also referred to excitations) are generated and conducted by circuits to generate photo-currents, wherein solar energy is transformed into electrical energy. For example, in a dye-sensitized solar cell (DSSC), a metal oxide semiconductor is sintered onto a conducting substrate and dye (photo sensitive substance) is adsorbed on the surface of the metal oxide to form a photo sensitive work electrode. An electrolyte is also provided to assist with conduction between the photo sensitive work electrode and its opposite electrode.

Liquid electrolyte and solid electrolyte are two types of electrolytes used in the DSSC. A wide selection of materials may be used as liquid electrolytes and advantageous thereof include high ionic conductivity and good penetrability. Thus, liquid electrolyte is commonly used in a DSSC for high photoelectric conversion efficiency.

However, liquid electrolyte also has some drawbacks, which are as follows: (a) requirement for a complicated packaging process and leakage due to a likelihood for reaction with packaging materials; (b) production difficulties and difficulty with application of solar cells made therefrom, due to toxic organic solvents contained therein; (c) likelihood for the organic solvents therein to vaporize due to their low boiling point and high vapor pressure; and (d) shape design limitations of solar cells made therefrom. Meanwhile, liquid electrolyte concentrations in respective solar cells may change due to leakage, resulting in an operating instability or even failure. Furthermore, costs are high due to the requirement for complicated processes or designs of the liquid electrolyte. Therefore, to address the above issues, solid electrolytes have been used as a replacement, and currently a trend in development is to use solid electrolytes.

For example, Kuruma (Langmuir 18 (2002) p. 10493) discloses using CuI as a solid electrolyte and triethylaime hydrothiocyanate as an inhibitor to suppress the growth of CuI crystalline. Disclosed photoelectric conversion efficiency was up to about 4.7%. However, the inorganic p-type semiconductor has poor stability, and poor hole transportation efficiency, and selection of suitable dyes is limited.

Grätzel (App. Phys. Lett. 79 (2001) p. 2085) discloses using an organic p-type semiconductor, 2,2′,7,7′-tetrakis-(N—N-di-p-methoxyphenylamine)9,9′-spiro-bifluoroene (spiro-MeOTAD), doped with tert-butylpyridine and Li(CF₃SO₂)₂N as the solid electrolyte. Disclosed photoelectric conversion efficiency was up to about 2.5%. Following, Grätzel further disclosed that by replacing the hydrophilic dye N719 with a hydrophobic dye Z907, photoelectric conversion efficiency may be increased to up to about 4.0%.

By using a p-type polymer semiconductor as the solid electrolyte, vacuum evaporation is not needed for forming a film by solution coating at room temperature and under atmospheric pressure. Furthermore, the p-type polymer semiconductor has good chemical stability, thermal stability, electrochemical stability and mechanical strength. For example, Liu (Adv. Mater. 20 (2008) p. 1) discloses a DSSC including a p-type polymer semiconductor, poly(3-hexylthiophene) (P3HT), as the solid electrolyte and an organic dye D102. Disclosed photoelectric conversion efficiency was up to about 2.5%.

However, the p-type polymer semiconductor has a large molecular structure that is difficult to penetrate to reach space between metal oxide semiconductors; especially if the metal oxide semiconductors are nanoparticles, which are commonly used today. Even if the p-type polymer semiconductor penetrates into the space between the nanoparticles, tight contact with the surface of the nanoparticles would still be difficult. Thus, photoelectric conversion efficiency of a solar cell having the polymer semiconductor is poor. For example, referring to FIG. 1, which shows a sectional view of a DSSC according to prior art, in which the polymer semiconductor 114 cannot tightly contact with the surfaces of the nanoparticles 106 adsorbed with dye 108.

Therefore, a novel method for forming a DSSC is needed for allowing a polymer solid-state electrolyte to effectively penetrate into space between nanoparticles of metal oxide semiconductors and tightly contact with the surfaces of the nanoparticles.

### BRIEF SUMMARY OF THE INVENTION

An embodiment of the present invention provides a dye-sensitized solar cell, comprising: a substrate having a first electrode formed thereon; a plurality of nanoparticles adsorbed with dye, overlying the first electrode; a solid electrolyte containing metal quantum dots completely covering the nanoparticles and fully filling the space between the nanoparticles; and a second electrode overlying the solid electrolyte.

An embodiment of the present invention provides a method for forming a dye-sensitized solar cell, comprising: providing a substrate having a first electrode formed thereon; forming a plurality of nanoparticles adsorbed with dye, overlying the first electrode; adding a solution containing a metal compound to the nanoparticles and a space between the nanoparticles; adding a monomer for heterogeneous in situ polymerization with the metal compound to form a solid electrolyte, wherein the solid electrolyte completely covers the nanoparticles and fully fills the space between the nanoparticles; and forming a second electrode overlying the solid electrolyte.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a sectional view of a conventional prior art dye-sensitized solar cell;

FIGS. 2A through FIG. 2F are sectional views of a dye-sensitized solar cell according to an embodiment of the present invention;

FIGS. 3A through FIG. 3B are sectional views of a dye-sensitized solar cell according to another embodiment of the present invention;

FIG. 4 is a SEM figure of a conventional prior art dye-sensitized solar cell; and

FIG. 5 is a SEM figure of a dye-sensitized solar cell according to an embodiment of the present invention.

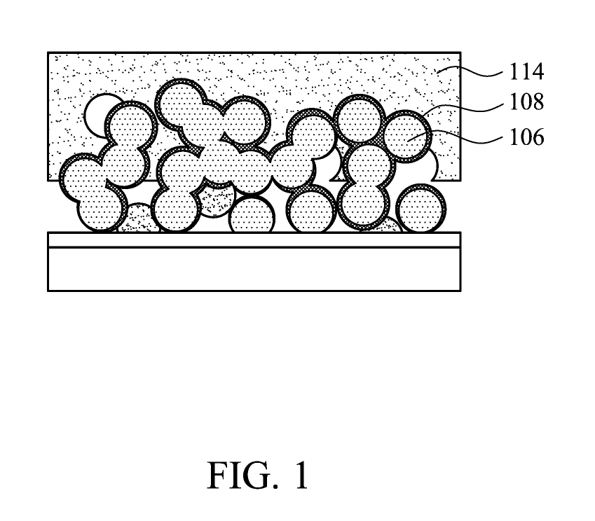

### DETAILED DESCRIPTION OF THE INVENTION

The following description is of the best-contemplated mode of carrying out the invention. This description is made for the purpose of illustrating the general principles of the invention and should not be taken in a limiting sense. These are, of course, merely examples and are not intended to be limiting. For example, the formation of a first feature over, above, below, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. The scope of the invention is best determined by reference to the appended claims.

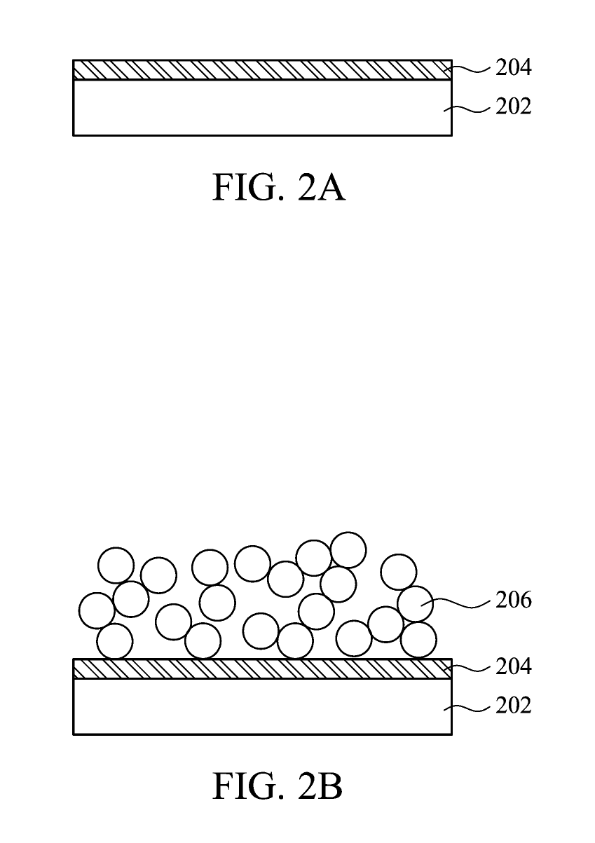

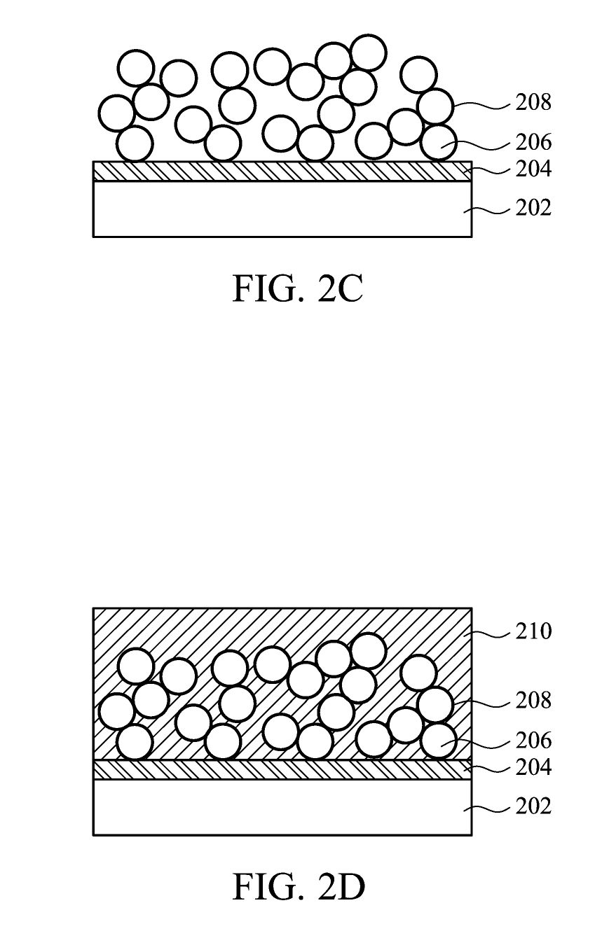

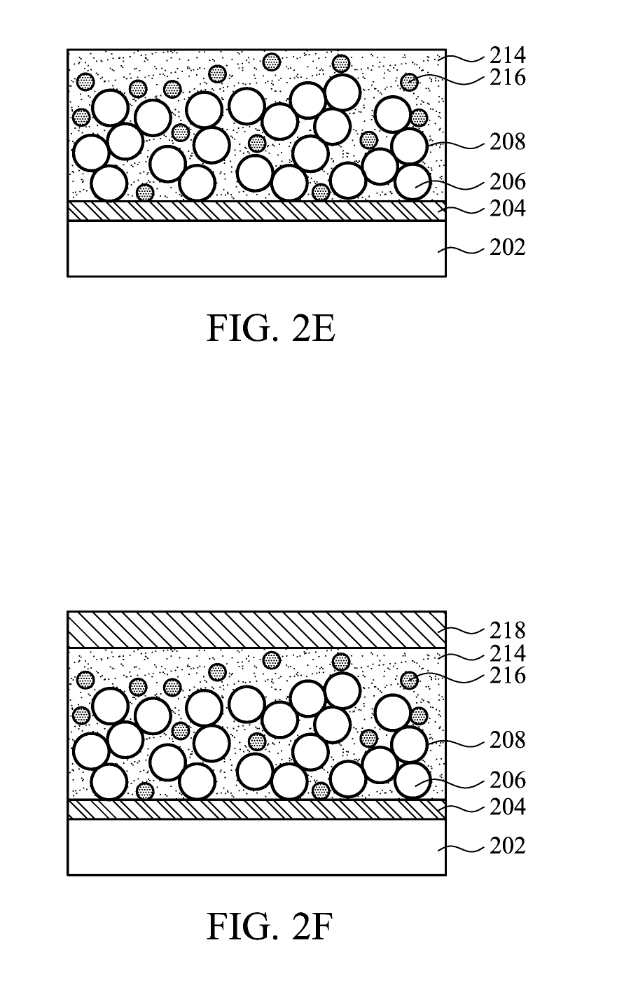

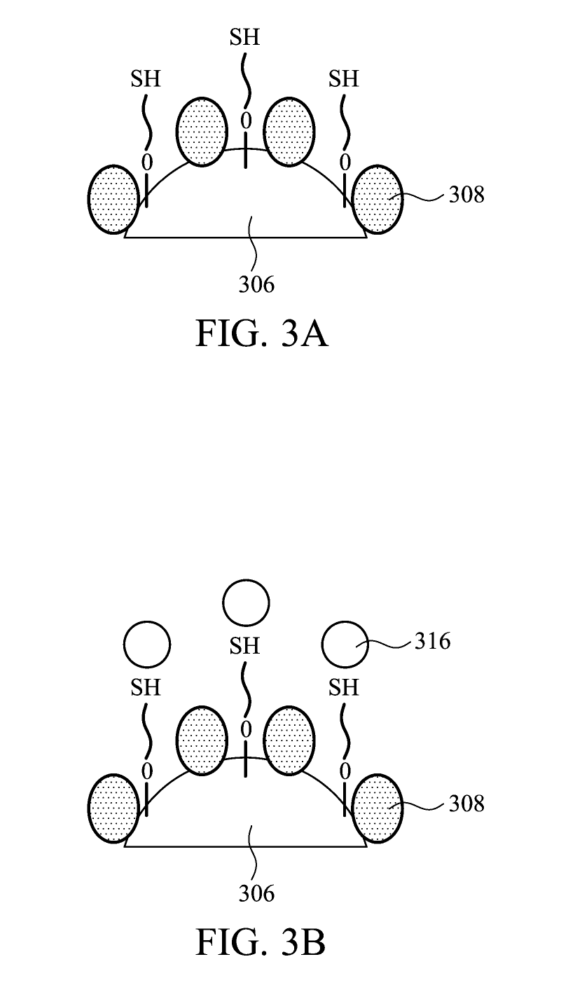

The present invention discloses a dye-sensitized solar cell. FIG. 2F illustrates a dye-sensitized solar cell according to an embodiment of the present invention which at least includes a substrate 202, a first electrode 204, a plurality of nanoparticles 206 adsorbed with dye 208, a solid electrolyte 214 containing metal quantum dots 216 and a second electrode 218. The solid electrolyte 214 containing the metal quantum dots 216 are formed by heterogeneous in situ polymerization of a monomer and a metal compound. Thus, the solid electrolyte 214 can completely cover the nanoparticles and fully fill the space between the nanoparticles. Furthermore, referring to FIG. 3, the nanoparticles 206 adsorbed with dye 208 may be modified to adsorb a portion of metal quantum dots 316 before performing heterogeneous in situ polymerization. This modification allows the dye 308 to adhere to the nanoparticles 306 more securely.

A method for forming dye-sensitized solar cell 200 according to an embodiment of the present invention is provided. Referring to FIG. 2A, a substrate 202 is provided. The substrate 202 may include a rigid substrate, a flexible substrate, a transparent substrate or a semi-transparent substrate. For example, the substrate 202 may be a glass substrate or a flexible transparent plastic substrate. A first electrode 204 is formed on the substrate 202 to provide an electron flow path. The first electrode 204 may be a transparent conductive layer made of material such as tin dioxide, zinc oxide, indium tin oxide, antinomy doped tin oxide, fluorine doped tin dioxide, aluminum doped zinc oxide or combinations thereof. Note that in this embodiment, the first electrode 204 serves as an anode.

FIG. 2B illustrates a plurality of nanoparticles 206 formed on the first electrode 204. The nanoparticles 206 may be coated on the first electrode 204 by a screen printing or blade coating process. The nanoparticles 206 may be metal oxide semiconductors, and preferably n-type semiconductors made of material such as TiO₂, SnO₂, ZnO, WO₃, Nb₂O₅, SrTiO₃ or any other semiconductor having an electrical potential that matches with that of the dye. In one preferred embodiment, the nanoparticles 206 may be anatase TiO₂. Then, the nanoparticles 206 coated on the first electrode 204 are calcined to from stacked nanoparticles 206 on the first electrode 204. In an embodiment, the nanoparticles 206 are calcined at a temperature from 400 to 500° C. for 30 to 120 minutes. The height of the stacked nanoparticles 206 is between about 500 and 4000 nm. The average size of the nanoparticles 206 is about 20 nm, which provides a large surface area for adsorbing dye.

FIG. 2C illustrates dye 208 adsorbed on the surface of the nanoparticles 206, for absorbing light and converting it to electrical energy. In one embodiment, the dye 208 may be an organic metal complex dye including porphyrins or organic Ru complexes, or an organic dye including coumarie dyes, indoline dyes, cyanine dyes or Rhodamine B dyes. Note that one skilled in the art may choose a suitable dye depending on the adsorbing ability or the redox potential between the dye 208 and the nanoparticles 206. Therefore, the above described dyes are merely illustrative and not limiting.

Referring to FIG. 2D, a solution containing a metal compound 210 is added to the surface of the nanoparticles 206 and the space between of the nanoparticles 206. The metal compound 210 may include HAuCl₄, AuCl₃, H₂Pt₆, K₂PtCl₆, PtCl₄ or combinations thereof. The solution may include alcohol, nitriles or any other solvents capable of penetrating into the space between the nanoparticles. In one embodiment, the solvent may be methanol, ethanol, isopropanol, acetonitrile or combinations thereof. In one preferred embodiment, the metal compound may have a reduction potential higher than about 0.7 V to dissociate Au³⁺ ions. The concentration of the metal compound may be between about 9×10⁻³ and 3×10⁻²M.

Referring to FIG. 2E, a monomer of the solid electrolyte is added to the surfaces of the nanoparticles 206 and the space between the nanoparticles 206. The monomer of the solid electrolyte 214 may be added by a coating or dripping process. The monomer preferably has an oxidization potential higher than about 0.4 V. Here, heterogeneous in situ polymerization occurs with reduction of the monomer with the metal compound adhered on the nanoparticles 206 or present in the space between the nanoparticles 206. Thus, completing formation of a solid electrolyte 214 containing metal quantum dots 216. It should be noted that the metal quantum dots 216 are formed by reduction of the metal compound, and thus the metal quantum dots 216 are electrically neutral or has an oxidation state lower than that of the metal compound. Polymerization may be performed at a temperature of about 25 to 50° C. for several seconds to minutes. Furthermore, since the reaction is in situ polymerization, the quantum dots 216 thus formed are contained in the solid electrolyte 214. In one embodiment, the solid electrolyte 214 may be polymerized by a monomer or an oligomer of a p-type semiconductor and includes 3,4-polyethylenedioxythiophene (PEDOT), poly(3-hexylthiophene) (P3HT), poly(3-butylthiophene) (P3BT), polythiophene (PTP), polypyrrole, or polyaniline, or derivatives thereof or combinations thereof. The solid electrolyte 214 may have a thickness of about 0.1 μm to 4 μm and contain metal quantum dots 216 having an average size of about 1 to 10 nm. It should be noted that the HOMO level of the solid electrolyte 214 is preferably higher than the LUMO level of the dye 208.

Because both the monomer of the solid electrolyte and the metal compound are small molecules and capable of penetrating to the surfaces of the nanoparticles and the space between the nanoparticles, heterogeneous in situ polymerization occurs directly on the surfaces of the nanoparticles and the space between the nanoparticles. Thus, the solid electrolyte according to the present invention completely covers the nanoparticles and fully fills the space between the nanoparticles. That is, the surfaces of the nanoparticles are tightly in contact with the solid electrolyte. As such, the problem of inefficient penetration due to large molecule size of the solid electrolyte is mitigated.

Furthermore, the metal compound also has a light-absorbing ability after it is reduced to the metal quantum dots. For example, gold quantum dots may absorb light having a wavelength of between about 410 nm and 675 nm. Therefore, the total absorption of the dye-sensitized solar cell can be enhanced or the absorption range may be broadened. In one embodiment, the overall absorption range of the dye and the metal quantum dots is between about 400 and 750 nm.

Finally, FIG. 2F illustrates a second electrode 218 formed on the solid electrolyte 214. The second electrode may include palladium, silver, aluminum, gold, platinum, alloys thereof, conducting polymers or combinations thereof. In one embodiment, the second electrode 218 may be formed by electroplating, electroless plating, evaporation sputtering, thermal cracking, or combinations thereof. In another embodiment, the second electrode 218 is formed by adding a metal salt onto the solid electrolyte 214. The metal salt may be directly reduced to the second electrode 218 by the solid electrolyte 214. The metal salt may include PdCl₂, HAuCl₄, H₂PtCl₆. Thus, completing formation of a solid-state dye-sensitized solar cell.

In the following, another embodiment according to the present invention will be described, which is characterized in that the nanoparticles adsorbed with dye are modified to adsorb the metal quantum dots before the metal compound is added.

Firstly, the same steps as in the above described embodiment is repeated to form the structure shown in FIG. 2, comprising a substrate 202, a first electrode 204, and nanoparticles 206 adsorbed with dye. Then, the nanoparticles adsorbed 206 with dye are modified to adsorb quantum dots. For example, the nanoparticles 206 adsorbed with dye may be dipped into a modifier solution, and the surfaces of nanoparticles 206 not covered by the dye are modified. FIG. 3A shows an enlarged view of the modified nanoparticles. The modifier may include a thio group, amine group or other groups capable of adsorbing quantum dots. For example, the modifier may include 3-mercaptopropyltrimethoxysilane (MPTMS), thiosalicylic acid (TSA) or 3-aminopropyltrimethoxysilane (APTMS).

FIG. 3B illustrates metal quantum dots 316 adsorbed on the modified nanoparticles 306. The metal quantum dots 316 may include any quantum dots known in the art, but preferably, gold quantum dots. Typically, the metal quantum dots 316 are prepared in a solution. When dipping the modified nanoparticles 306 in the solution, the metal quantum dots 316 are adsorbed on the surfaces of the modified nanoparticles 306. Accordingly, a portion of metal quantum dots 316 may be adsorbed on the modified nanoparticles 306 before adding the metal compound. This step allows the dye 308 to adhere to the nanoparticles 306 more securely. Then, the steps illustrated along with FIG. 2D to FIG. 2F are repeated to complete formation of a solid-state dye-sensitized solar cell.

To summarize, the present invention discloses a novel solid-state dye-sensitized solar cell comprising a solid electrolyte containing metal quantum dots. The solid electrolyte is directly formed on the nanoparticles and in the space between the nanoparticles by heterogeneous in situ polymerization carried out by a monomer of the solid electrolyte and a metal compound. Thus, the solid electrolyte may completely cover the nanoparticles and fully fill the space between the nanoparticles as well as tightly contact the surfaces of the nanoparticles. Furthermore, the metal quantum dots are formed by reduction of the metal compound during the heterogeneous in situ polymerization process. Since the metal quantum dots may have a nano-scale light-absorbing ability, total light absorption of the dye-sensitized solar cell may be enhanced or the overall absorption range may be further broadened. Thus, the photoelectric conversion efficiency of the dye-sensitized solar cell can be effectively enhanced. Furthermore, the present invention provides a method for forming the dye-sensitized solar cell without using vacuum evaporation. For example, the polymer semiconductor is formed at room temperature and under atmospheric pressure and a metal salt can be reduced to form an electrode on the solid electrolyte by the solid electrolyte to facilitate fabrication of the solar cell. In addition, the method may further include allowing the nanoparticles to adhere to dye more securely and adsorb more quantum dots on their surfaces. Accordingly, light absorption of the dye-sensitized solar cell can be further enhanced.

### Comparative Example 1

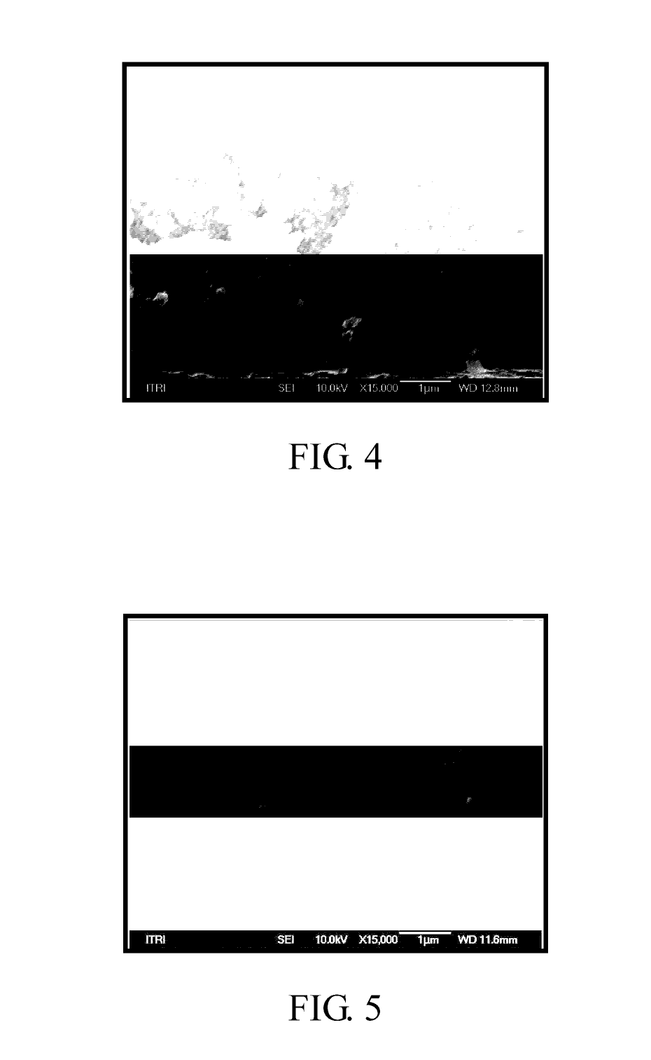

TiO₂ nanoparticles were coated onto a conducting glass containing fluorine doped tin dioxide by a screen printing process and calcined at a temperature of between 400 and 500° C. for 30 to 60 mins to form a TiO₂ electrode. The TiO₂ electrode was dipped in Z907 (dye; 5×10⁻⁴M) for 24 hours. Then, poly(3-hexylthiophene) (P3HT) was coated onto the TiO₂ electrode. The scanning electron microscopy (SEM) figure of the TiO₂ electrode is shown in FIG. 4, wherein a polymer layer failed to penetrate into the TiO₂ electrode.

### Example 1

TiO₂ nanoparticles were coated onto a conducting glass containing fluorine doped tin dioxide by a screen printing process and calcined at a temperature of between 400 and 500° C. for 30 to 60 mins to form a TiO₂ electrode. The TiO₂ electrode was dipped in Z907 (dye; 5×10⁻⁴M) for 24 hours. Then, a 1 wt % HAuCl₄ solution was added to the TiO₂ electrode and then the TiO₂ electrode was dried. Next, an acetonitrile solution containing 3-hexylthiophene was added to the dried TiO₂ electrode for heterogeneous in situ polymerization at 30° C. for about 1 min and a deep blue solid electrolyte (P3HT) containing gold quantum dots was formed (4 μm in thickness). The scanning electron microscopy (SEM) figure of the TiO₂ electrode is shown in FIG. 5. Unlike Comparative Example 1, the solid electrolyte was completely filled in the space between TiO₂ nanoparticles.

### Comparative Example 2

TiO₂ nanoparticles were coated onto a conducting glass containing fluorine doped tin dioxide by a screen printing process and calcined at a temperature of between 400 and 500° C. for 30 to 60 mins to form a TiO₂ electrode. The TiO₂ electrode was dipped in Z907 (dye; 5×10⁻⁴M) for 24 hours. Then, 3,4-polyethylenedioxythiophene (PEDOT) was coated onto the TiO₂ electrode. Then, a Pt electrode was disposed on the TiO₂ electrode to complete formation of a dye-sensitized solar cell. The dye-sensitized solar cell had an open-circuit voltage of 0.66 V.

### Example 2

TiO₂ nanoparticles were coated onto a conducting glass containing fluorine doped tin dioxide by a screen printing process and calcined at a temperature of between 400 and 500° C. for 30 to 60 mins to form a TiO₂ electrode. The TiO₂ electrode was dipped in Z907 (dye; 5×10⁻⁴M) for 24 hours. Then, a 1 wt % HAuCl₄ solution was added to the TiO₂ electrode and then the TiO₂ electrode was dried. Next, an acetonitrile solution containing 3,4-ethylenedioxythiophene (EDOT) was added to the dried TiO₂ electrode for heterogeneous in situ polymerization at 30° C. for 10 sec and a deep blue solid electrolyte (PEDOT) containing gold quantum dots was formed (4 μm in thickness). Then, a Pt electrode was disposed on the TiO₂ electrode to complete a dye-sensitized solar cell. The dye-sensitized solar cell had an open-circuit voltage of between 0.8 V and 0.9V.

### Example 3

The same procedures as in Example 2 were repeated except that the TiO₂ electrode adsorbed with dye was dipped into a toluene solution containing 2 wt % 3-mercaptopropyltrimethoxysilane for 4 to 12 hours and then dipped into the a solution containing 1 wt % gold quantum dots for 4 hours before adding the HAuCl₄ solution.

### Example 4

The same procedures as in Example 2 were repeated, except that the PdCl₂ was directly added to form a Pd film on the solid electrolyte (PEDOT).

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A dye-sensitized solar cell, comprising
a substrate having a first electrode formed thereon;
a plurality of nanoparticles adsorbed with dye, overlying the first electrode;
a solid electrolyte containing metal quantum dots completely covering the nanoparticles and fully filling the space between the nanoparticles; and
a second electrode overlying the solid electrolyte.

2. The dye-sensitized solar cell as claimed in claim 1, wherein the nanoparticles comprise metal oxide semiconductors.

3. The dye-sensitized solar cell as claimed in claim 1, wherein the dye comprises organic dye or organometallic dye.

4. The dye-sensitized solar cell as claimed in claim 1, wherein the metal quantum dots are electrically neutral or charged.

5. The dye-sensitized solar cell as claimed in claim 1, wherein the metal quantum dots comprise gold quantum dots.

6. The dye-sensitized solar cell as claimed in claim 1, wherein the solid electrolyte comprises 3,4-polyethylenedioxythiophene (PEDOT), poly(3-hexylthiophene) (P3HT), poly(3-butylthiophene) (P3BT), polythiophene (PTP), polypyrrole, or polyaniline, or derivatives thereof or combinations thereof.

7. The dye-sensitized solar cell as claimed in claim 1, further comprising thio groups or amine groups on the nanoparticles.

8. The dye-sensitized solar cell as claimed in claim 7, wherein the metal quantum dots are adsorbed on the nanoparticles.

9. The dye-sensitized solar cell as claimed in claim 1, wherein the metal quantum dots increase the amount of light absorption of the dye-sensitized solar cell.

10. The dye-sensitized solar cell as claimed in claim 1, wherein the second electrode comprises palladium, silver, aluminum, platinum, gold, conducting polymers or combinations thereof.

11. A method for forming a dye-sensitized solar cell, comprising:
providing a substrate having a first electrode formed thereon;
forming a plurality of nanoparticles adsorbed with dye, overlying the first electrode;
adding a solution containing a metal compound to the nanoparticles and a space between the nanoparticles;
adding a monomer for heterogeneous in situ polymerization with the metal compound to form a solid electrolyte, wherein the solid electrolyte completely covers the nanoparticles and fully fills the space between the nanoparticles; and
forming a second electrode overlying the solid electrolyte.

12. The method as claimed in claim 11, wherein the dye comprises organic dye or organometallic dye.

13. The method as claimed in claim 11, wherein the metal compound has a reduction potential higher than about 0.7V.

14. The method as claimed in claim 11, wherein the solid electrolyte has an oxidation potential higher than about 0.4V.

15. The method as claimed in claim 11, wherein the solution comprises alcohols, nitriles, or any other solvents capable of penetrating into the space between the nanoparticles, or combinations thereof.

16. The method as claimed in claim 11, wherein the solid electrolyte comprises 3,4-polyethylenedioxythiophene (PEDOT), poly(3-hexylthiophene) (P3HT), poly(3-butylthiophene) (P3BT), polythiophene (PTP), polypyrrole, or polyaniline, or derivatives thereof or combinations thereof.

17. The method as claimed in claim 11, wherein the solid electrolyte comprises metal quantum dots.

18. The method as claimed in claim 17, wherein the metal quantum dots are formed by reduction of the metal compound during the heterogeneous in situ polymerization process.

19. The method as claimed in claim 18, wherein the metal quantum dots are electrically neutral or in an oxidation state lower than that of the metal compound.

20. The method as claimed in claim 19, wherein the metal quantum dots comprise gold quantum dots.

21. The method as claimed in claim 11, further comprising modifying the nanoparticles before adding the solution.

22. The method as claimed in claim 21, further comprising adding metal quantum dots which are adsorbed on the modified nanoparticles before adding the solution.

23. The method as claimed in claim 11, wherein the second electrode is formed by an electroplating, electroless plating, evaporation sputtering, or thermal cracking process or combinations thereof.

24. The method as claimed in claim 11, wherein the second electrode is formed by reduction of a metal salt by the solid electrolyte.

25. The method as claimed in claim 24, wherein the metal salt comprises PdCl₂, HAuCl₄, H₂PtCl₆ or combinations thereof.
